(19) United States
(12) Patent Application Publication
(10) Pub. No.: US 2007/0264807 A1
(43) Pub. Date: Nov. 15, 2007

(54) Cleaining Process and Operating Process for a Cvd Reactor

(76) Inventors: Stefano Leone, S. Agata Li Battiati (IT); Marco Mauceri, Catania (IT); Giuseppe Abbondanza, Trappeto (IT); Danilo Crippa, Novara (IT); Gianluca Valente, Milano (IT); Maurizio Masi, Milano (IT); Franco Preti, Milano (IT)

Correspondence Address: KATTEN MUCHIN ROSENMAN LLP, 575 MADISON AVENUE, NEW YORK, NY, 10022-2585, US

(21) Appl. No.: 11/660,689

(22) PCT Filed: Jul. 12, 2005
(86) PCT No.: PCT/EP05/53328

§ 371 Date: Feb. 20, 2007

(30) Foreign Application Priority Data
Aug. 30, 2004 (IT) MI2004A001677

(51) Int. Cl. H01L 21/20; B08B 7/00; C23C 16/00; C23C 16/32; C23C 16/44

(52) U.S. Cl. 438/507; 118/716; 134/19

(57) ABSTRACT

The present invention relates to a process for cleaning the reaction chamber (12) of a CVD reactor, comprising the steps of heating the chamber walls to a suitable temperature and introducing a gas flow into the chamber, this cleaning process may be advantageously used within an operating process of a CVD reactor for depositing semiconductor material onto substrates inside a chamber; this operating process envisages a growth process comprising the sequential and cyclical loading of the substrates into the chamber (12), deposition of semiconductor material onto the substrates and unloading of the substrates from the chamber (12); after unloading a process for cleaning the chamber (12) is performed. The invention also relates to process for cleaning the entire CVD reactor, which envisages, together with heating, the presence of chemical etching components in the gas flow.

### DESCRIPTION

The present invention relates to a cleaning process and to an operating process for a CVD reactor.

As is known, CVD (Chemical Vapour Deposition) reactors are used to perform epitaxial growth processes during which thin and uniform layers of material are deposited onto substrates.

In the microelectronics sector, CVD reactors are used to deposit thin layers of semiconductor material onto substrates and then prepare the slices used in the production of electronic components, in particular integrated circuits. During the growth process, the semiconductor material is deposited both on the substrate and on the internal walls of the reaction chamber: this is particularly true in the case of so-called “hot wall” CVD reactors since the material is deposited only when the temperature is fairly high.

With each process, a new thin layer of material is deposited on the internal walls of the chamber; after various processes, the walls have a thick layer of material. This thick layer of material modifies the geometry of the chamber, thus influences the flow of the reaction gases and therefore influences the further growth processes. Moreover, this thick layer of material is not perfectly compact and, during further growth processes, small particles may become detached from this layer and damage the substrates being grown if they fall on top of them.

At present, the semiconductor material which is most widely used by the microelectronics industry is silicon. A very promising material is silicon carbide, even though it is currently not yet greatly used by the microelectronics industry.

In order to grow epitaxially silicon carbide having the high quality required by the microelectronics industry, very high temperatures are required, namely temperatures higher than 1500° C. and therefore much higher than those which are necessary for epitaxial growth of silicon, generally ranging between 1100° C. and 1200° C. In order to obtain these high temperatures, “hot-wall” CVD reactors are particularly suitable.

Therefore, the CVD reactors for epitaxial growth of silicon carbide suffer in particular from the problem associated with the deposition of material on the internal walls of the reaction chamber. Moreover, silicon carbide is a material which is particularly difficult to remove both mechanically and chemically.

The solution usually adopted to solve this problem is that of periodically disassembling the reaction chamber from the reactor and cleaning it mechanically and/or chemically; this operation requires a lot of time and therefore involves long stoppage of the reactor; moreover, often, after a certain number of cleaning operations, the chamber must be discarded or treated.

Moreover, especially in the reactor sections upstream and downstream of the actual reaction chamber, there may be silicon deposits which must also be removed.

The general object of the present invention is that of providing a cleaning process for reaction chambers of CVD reactors and for CVD reactors, which overcomes the abovementioned drawbacks.

This object is substantially achieved by the cleaning process having the functional features described in the independent claim 1; further advantageous aspects of this process are described in the dependent claims.

According to a further aspect, the present invention also relates to an operating process for CVD reactors which uses this cleaning process and which has the functional features described in the independent claim 12; further advantageous aspects of this process are described in the dependent claims.

The present invention will become clear from the following description to be considered in conjunction with the accompanying drawings in which:

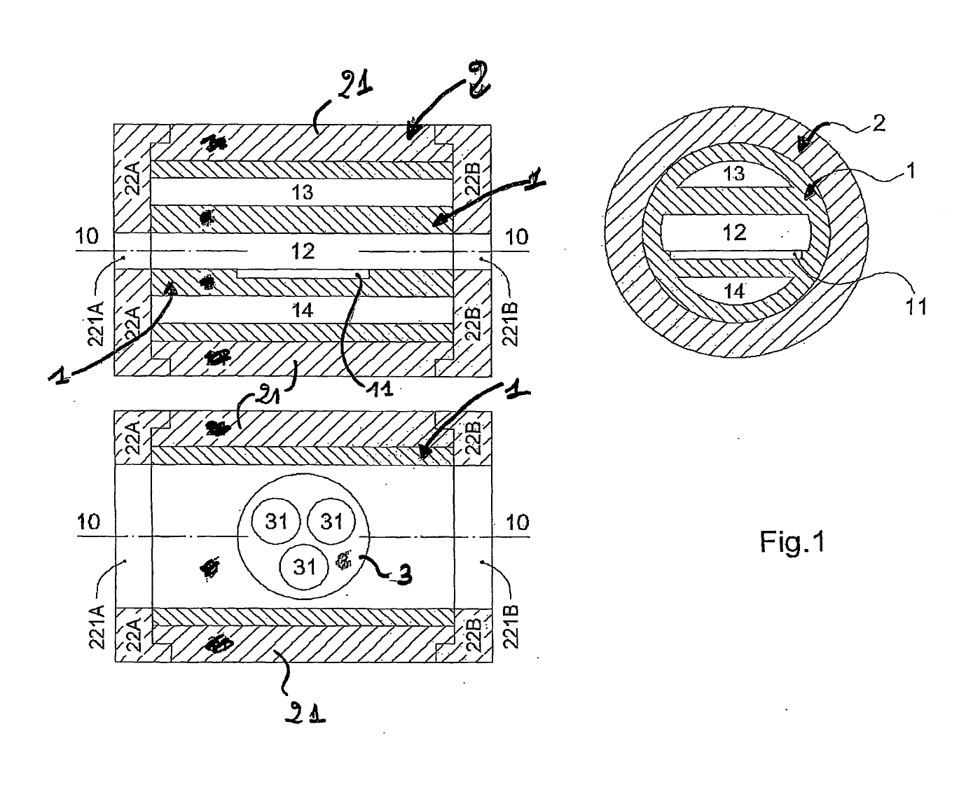

FIG. 1 shows a cross-sectional side view, a cross-sectional front view and a cross-sectional view, from above, of a reaction chamber surrounded by an insulating shell, to which the cleaning process according to the present invention may be applied;

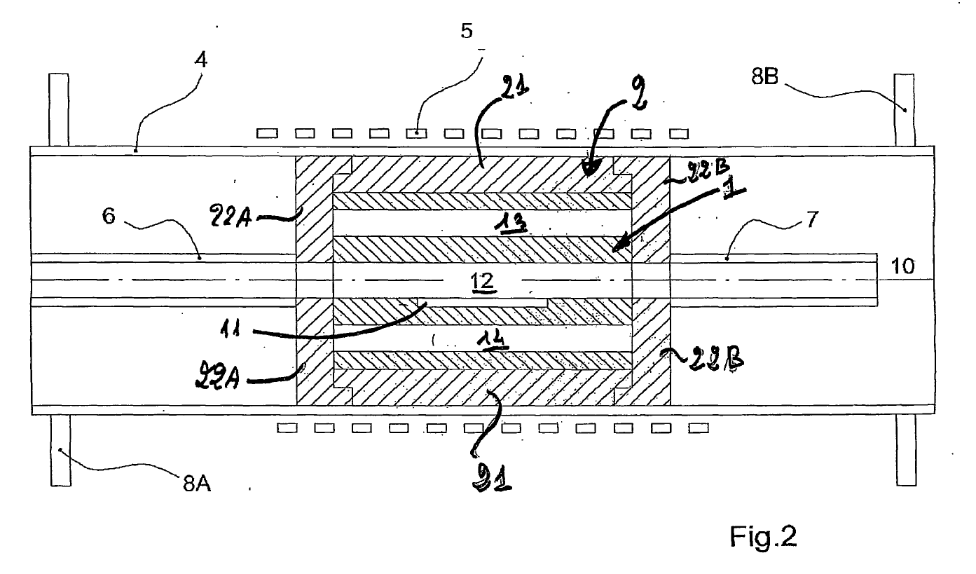

FIG. 2 shows a part of a CVD reactor comprising the assembly according to FIG. 1;

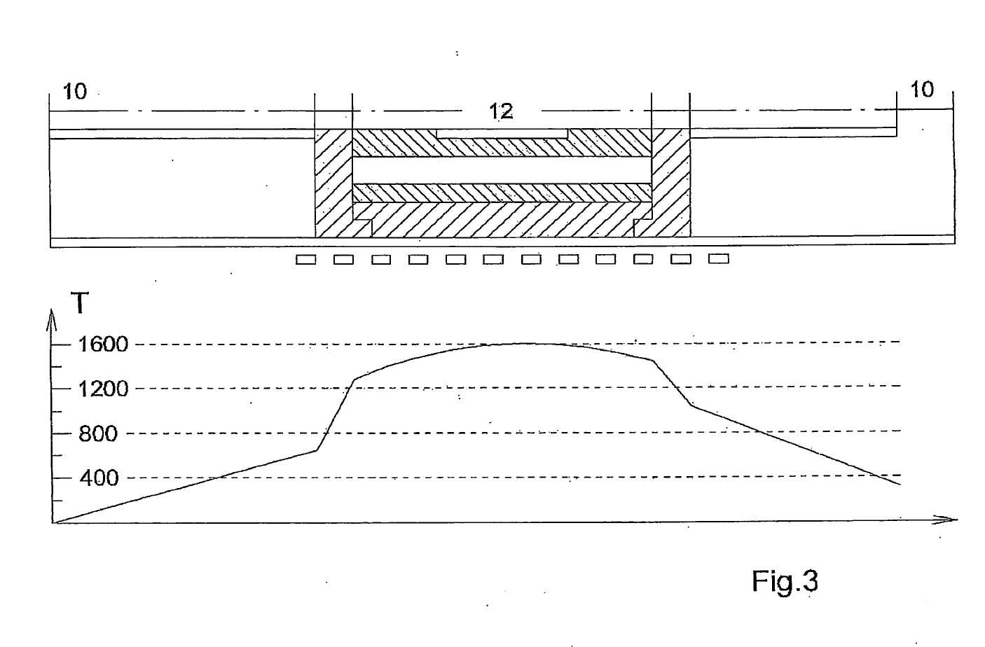

FIG. 3 shows a spatial diagram for the temperature inside the reactor in FIG. 2; and

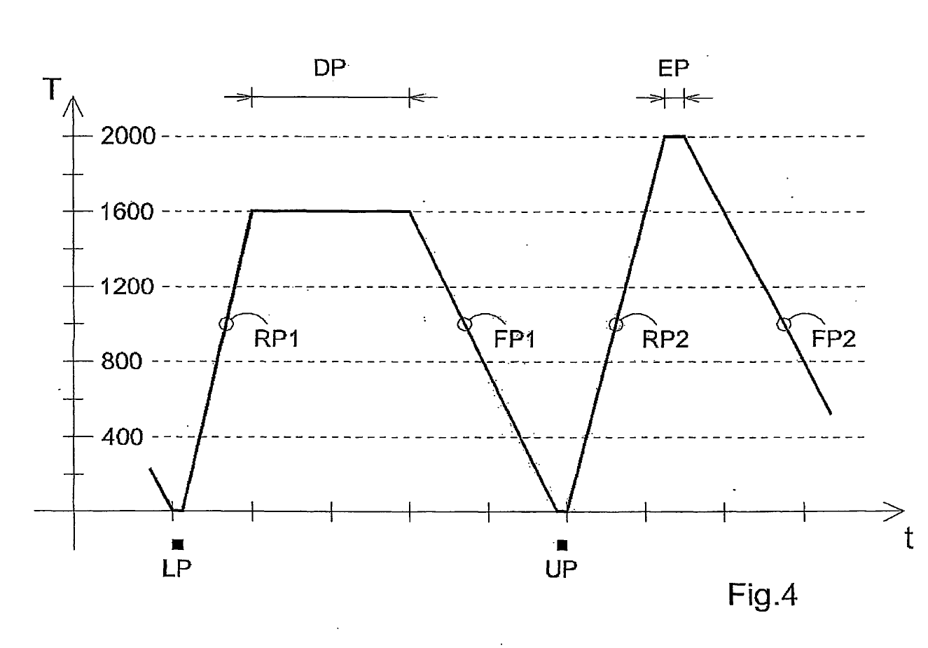

FIG. 4 shows a time/temperature diagram relating to the operating process according to the present invention performed in the reactor according to FIG. 2.

Both this description and these drawings are to be considered solely for illustrative purposes and therefore are not limiting; moreover, it must be remembered that these figures are schematic and simplified.

FIG. 1 shows the assembly consisting of a reaction chamber, indicated in its entirety by the reference number 1, and a surrounding shell, indicated in its entirety by the reference number 2.

FIG. 1 shows on the top right a front view of the assembly sectioned centrally, on the top left a side view of the assembly sectioned centrally and on the bottom left a view, from above, of the assembly sectioned centrally.

The cleaning process according to the present invention may be applied advantageously, for example, to the chamber 1 shown in FIG. 1. This chamber is particularly suitable for use in CVD reactors for the epitaxial growth of silicon carbide.

The chamber 1 has a cavity 12 for housing substrates on which layers of semiconductor material are deposited; for this purpose, the cavity 12 has a bottom wall which is substantially flat and for being arranged in a substantially horizontal position inside a CVD reactor; the cavity 12 is surrounded by other walls, in particular by an upper wall and by two side walls. The reaction gases flow longitudinally through the cavity 12. The chamber 1 is suitable to be heated in such a way as to heat the walls of the cavity 12 and therefore also the reaction gases which flow inside it. Typically, the chamber 1 is suitable to be heated by means of electromagnetic induction; for this purpose, the chamber 1 is typically made of graphite and lined with a protective layer of silicon carbide or tantalum carbide or niobium carbide. The chamber 1 shown in FIG. 1 extends uniformly along an axis 10 (with a length of 300 mm) and its cross-section has the external form of a circle (with a diameter of 270 mm); alternatively, this cross-section could have the form of a polygon or an ellipse. The cross-section of the cavity 12 shown in FIG. 1 has the internal form substantially of a rectangle (with a width of 210 mm and a height of 25 mm); this cross-section could have a different form.

The cleaning process according to the present invention is particularly useful in the case where the surface of the reaction chamber which faces the substrates (in the case of FIG. 1, the upper wall of the cavity 12) is very close to the said substrates; in fact, in this case, any particles which become detached from this surface (more precisely from layers grown on this surface) fall onto the substrates before they are conveyed away by the flow of reaction gases.

In the case where the walls of the cavity 12 of the chamber 1 are lined with a protective layer, for example, tantalum carbide or niobium carbide, the adhesion of the material which is deposited onto the walls during the growth process is limited and therefore the formation of particles is more probable; this is particularly true if the material of the protective layer and the material which is deposited are different owing to a difference in the crystal structure; this is the case, for example, of reaction chambers which are made of graphite and lined with tantalum carbide or niobium carbide when they are used for silicon carbide growth processes.

In reaction chambers of the type shown in FIG. 1, the substrates generally rest on a tray in order to facilitate loading thereof before the start of the growth process and unloading thereof at the end of the growth process. In the example according to FIG. 1, the tray is indicated by the reference number 3 and is able to support three circular substrates inside three corresponding hollows 31; at the present time, the number of substrates may vary from a minimum of one to a maximum of twelve and their diameter may vary from a minimum of two inches to a maximum of six inches, but this is not relevant for the purposes of the present invention; obviously, with an increase in the number of substrates there is a reduction in their diameter.

In reaction chambers of the type shown in FIG. 1, it is advantageous to envisage that the substrate support is rotatable so as to favour uniform deposition onto the substrates; achieving proper cleaning of the reaction chamber and therefore removal of the material deposited on the internal walls of the chamber is useful also for ensuring effective and efficient rotation of the tray. In the example according to FIG. 1, the tray 3 is rotatable even though the means for achieving its rotation have not been shown; various solutions for obtaining rotation of the tray are known to the person skilled in the art, for example, from the document WO2004/053189.

In the chambers with tray such as that shown in FIG. 1, it is advantageous to envisage that the tray is housed inside a recess of the bottom wall of the cavity so that the internal surface of the cavity does not have sudden projections or depressions; ensuring proper cleaning of the reaction chamber and therefore removal of the material deposited on the bottom wall of the cavity is useful also for keeping the surface of the tray and the surface of the wall aligned. In the example according to FIG. 1, the (rotatable) tray 3 has the shape of a thin disk (with a diameter of 190 mm and thickness of 5 mm) and is housed inside a recess 11 of the bottom wall of the cavity 12 having a circular shape.

The tray of a chamber such as that shown in FIG. 1 generally acts also as a susceptor, i.e. an element which heats up by means of electromagnetic induction and which directly heats the substrates which its supports.

The chamber 1 according to FIG. 1 has two large through-holes 13 and 14 inside which the reaction gases do not flow; therefore, there is no deposition of material on the walls of these holes and therefore these walls are not of great significance for the purposes of the present invention.

Many functional and constructional details of a chamber such as that shown in FIG. 1, including the function and structure of the holes 13 and 14, may be obtained from the documents WO2004/053187 and WO2004/053188 which are incorporated herein by way of reference.

The reaction chamber of an epitaxial reactor must be physically isolated from the environment surrounding it in order to control precisely the reaction environment. The reaction chamber of an epitaxial reactor must also be thermally insulated from the environment which surrounds it; in fact, during the epitaxial growth processes, the chamber and its environment are at a temperature ranging between 1000° C. and 2000° C. (depending on the material to be deposited) and it is therefore important to limit the loss of heat; for this purpose, the chamber is surrounded by a thermal insulation structure.

In the example according to FIG. 1, the chamber 1 is surrounded by a thermal insulating shell 2; the shell 2 may be made, for example, of porous graphite, namely a refractory and thermally insulating material; the shell 2 comprises a cylindrical body 21 and two side covers (22A on the left and 22B on the right) which are mounted on the body 21 by means of a peripheral ring which improves the thermal insulation of the joining zone between body and covers. The two covers 22A and 22B have respectively two openings 221A and 221B with substantially the same cross-section as the cavity 12 for entry of the reaction gases and outflow of the exhaust gases; obviously, these openings are substantially aligned with the cavity 12; these openings, in particular the opening 221A, are also used for loading and unloading the substrates or rather the tray with the substrates, by means of suitable manual or automatic tools.

FIG. 2 shows part of a CVD reactor comprising the assembly according to FIG. 1.

The assembly according to FIG. 1 is inserted into the central zone of a long quartz tube 4, for example two or three or four times the length of the reaction chamber; the function of the tube 4 is, among other things, that of dispersing the radiating energy which emerges from the side covers 22 and in particular from the openings 221.

An inlet union 6 and an outlet guide 7 are envisaged; these elements are made typically of quartz; the inlet union 6 has the function of connecting a reaction-gas supply duct (not shown in FIG. 2) with a circular cross-section, to the opening 221A of the cover 22A, which has a rectangular and very flattened cross-section; the outlet guide 7 has the function of guiding the discharge gases towards a duct for discharging the exhaust gases (not shown in FIG. 2).

The tube 4, in the central zone, has wound around it, in the region of the assembly according to FIG. 1, the solenoid 5 which generates the electromagnet field that heats the chamber 1 by means of induction.

The two ends of the tube 4 are provided with two lateral flanges, i.e. a left-hand flange 8A and right-hand flange 8B, for fixing the tube to the housing of the epitaxial reactor.

As already mentioned, the assembly according to FIG. 2 is particularly suitable for carrying out processes for epitaxial growth of silicon carbide since it is designed in particular to produce and maintain very high temperatures inside the cavity 12 of the reaction chamber.

FIG. 3 shows a typical temperature diagram for the assembly according to FIG. 2 along the axis of symmetry 10 during a process for epitaxial growth of silicon carbide; the top part of FIG. 3 shows partially the assembly of FIG. 2 so that the spatial correspondence may be understood more easily.

At the start of the union 6, the temperature corresponds to the ambient temperature, for example 20° C.; the temperature then rises gradually along the union 6; there is then a rapid increase in the region of the opening 221A of the cover 22A; inside the cavity 12 the temperature is fairly constant in particular in the central zone of the cavity 12 where the tray 3 with the substrates is situated, namely typically a temperature ranging between 1500° C. and 1700° C. and preferably between 1550° C. and 1650° C.; then there is a sharp drop in the region of the opening 221B of the cover 22B; finally the temperature gradually falls along the guide 7; the temperature at the inlet of the cavity 12 is lower than that at the outlet of the cavity 12 since the reaction gases heat up also as a result of flowing inside the cavity 12.

In a non-uniform temperature situation such as that shown in FIG. 3, the deposition of material along the walls is not uniform; moreover, with reference to FIG. 2, there is deposition of material not only along the walls of the cavity 12, but also along the union 6, along the guide 7 and in the region of the two openings 221; for example, in the low-temperature zones, layers of silicon are deposited and, in the high-temperature zones, layers of silicon carbide are deposited. Obviously, it is advantageous to clean possibly all the parts of the reactor independently of the material deposited.

The process for cleaning the reaction chamber of a CVD reactor, according to the present invention, comprises essentially the steps of:
heating the walls of the chamber to a temperature not lower than that for start of sublimation of the silicon carbide;
introducing a gas flow into the chamber.

In this way it is possible to remove easily and of the opening 221A of the cover 22A; inside the cavity 12 the temperature is fairly constant in particular in the central zone of the cavity 12 where the tray 3 with the substrates is situated, namely typically a temperature ranging between 1500° C. and 1700° C. and preferably between 1550° C. and 1650° C.; then there is a sharp drop in the region of the opening 221B of the cover 22B; finally the temperature gradually falls along the guide 7; the temperature at the inlet of the cavity 12 is lower than that at the outlet of the cavity 12 since the reaction gases heat up also as a result of flowing inside the cavity 12.

In a non-uniform temperature situation such as that shown in FIG. 3, the deposition of material along the walls is not uniform; moreover, with reference to FIG. 2, there is deposition of material not only along the walls of the cavity 12, but also along the union 6, along the guide 7 and in the region of the two openings 221; for example, in the low-temperature zones, layers of silicon are deposited and, in the high-temperature zones, layers of silicon carbide are deposited. Obviously, it is advantageous to clean possibly all the parts of the reactor independently of the material deposited.

The process for cleaning the reaction chamber of a CVD reactor, according to the present invention, comprises essentially the steps of:
heating the walls of the chamber to a temperature not lower than that for start of sublimation of the silicon carbide;
introducing a gas flow into the chamber.

In this way it is possible to remove easily and effectively the material deposited on the walls of the chamber and also on other parts close to the chamber and affected both by the high temperature and by the gas flow. Typically and advantageously, in order to convey the gas, the same ducts used for the growth processes will be used and, for heating the chamber, the same means used for the growth processes will be used. In order to implement this process it is therefore not necessary to disassemble at all either the CVD reactor or its reaction chamber.

Owing to the temperature, the molecules of the deposited material tend to leave the solid wall and pass into the gaseous phase; the gas flow reduces the partial pressure of the species in the gaseous phase and therefore increases considerably this migration; the effect of these two phenomena is the removal of the deposited material; this effect is further favoured by the low crystallographic quality of the material deposited.

In the case of the reaction chamber and therefore the layers of SiC, cleaning is performed under optimum conditions by means of heating to a suitable temperature and the gas flow has the main purpose of conveying away the SiC vapours thus formed.

When, on the other hand, the cleaning process also concerns other components of the CVD reactor, where silicon deposits may be present and where the temperature reaches minimum values, then heating must be associated with chemical etching performed by means of suitable components of the gas flow which is introduced before the cleaning process.

Basically, two parameters are associated with the cleaning process according to the present invention: the temperature and the composition of the gas.

The gas used in the cleaning process according to the present invention may comprise only one chemical species or several chemical species.

The chemical species which may be advantageously used in the process according to the present invention include noble gases since they are highly inert and therefore any residues inside the reaction chamber do not create problems for the ensuing growth processes; typically it is possible to use helium or argon, which species is already commonly used by the microelectronics industry as a carrier gas.

The chemical species which may be advantageously used in the process according to the present invention also include hydrogen: this has reactive properties in relation to some materials; moreover, hydrogen has a very low molecular weight and therefore the coefficient of diffusion of the chemical species which are formed as a result of heating of the walls is very high. Hydrogen also has the major advantage of having a low cost.

Other chemical species which may be advantageously used in the process according to the present invention are hydrochloric acid or hydrobromic acid; as is known, these substances have notable chemical etching properties in respect of many materials and therefore have the effect of chemical removal in addition to physical removal.

The use, therefore, of several chemical species is particularly advantageous when it is required to remove different materials in different points; for example, as already mentioned, inside the reactor according to FIG. 2 there may be silicon deposits in some points and silicon carbide deposits in other points.

A first advantageous combination of chemical species envisages hydrochloric acid and a noble gas; hydrochloric acid is particularly effective in removing silicon and a noble gas is particularly effective in removing silicon carbide at a high temperature.

A second advantageous combination of chemical species envisages hydrochloric acid and hydrogen; hydrochloric acid is particularly effective in removing silicon and hydrogen is particularly effective in removing silicon carbide at a high temperature.

The temperature used in the cleaning process according to the present invention is high, typically higher than 1800° C., preferably higher than that of the process for growth on substrates (for silicon, this temperature is typically in the range of 1100° C.-1200° C. and, for silicon carbide, this temperature is typically in the range of 1550° C.-1650° C.). A high temperature results in fast removal of the material from the walls (and therefore a fast cleaning process), but it is appropriate and advantageous to choose a temperature which is not too high in order to avoid having to modify the reactor solely as a result of the cleaning process.

For the purposes of the present invention, the most significant temperature is that of the walls of the reaction chamber (with reference to FIG. 1 and FIG. 2, the walls of the cavity 12); however, in CVD reactors with “hot wall” reaction chambers, such as that shown in FIG. 1, the temperature of the chamber environment and the temperature of the chamber walls do not differ significantly.

Temperatures which have proved suitable for obtaining an effective and efficient cleaning action preferably range between 1800° C. and 2400° C., more preferably between 1900° C. and 2000° C.; these temperatures are suitable also for removing silicon carbide, while in the case of silicon lower temperatures could also be used.

The cleaning process according to the present invention may comprise:
a first period during which the temperature of the chamber walls is increased;
a second period during which the temperature of the chamber walls is maintained;
a third period during which the temperature of the chamber walls is reduced.

With reference for example to FIG. 4, the first period corresponds to the diagram section indicated by the reference RP2, the second period corresponds to the diagram section indicated by the reference EP, and the third period corresponds to the diagram section indicated by the reference FP2. In the reactor partially shown in FIG. 2, the increase in temperature of the walls of the cavity 12 is obtained by energizing the solenoid 5, the temperature is maintained by controlling energization of the solenoid 5 by means of a suitable (and known) temperature control system, and reduction of the temperature may be obtained, for example, by interrupting the power supply to the solenoid 5.

Of the three periods, the most effective period for removal of the material from the walls is the second period because the temperature is higher; however, also the final part of the first period and the initial part of the third period may play a part.

A third very important parameter for controlling the cleaning process is the gas flow. In the simplest case, the gas flow is the same for the entire duration of the cleaning process. Purely by way of example, the values of the parameters of a process example are indicated: flowrate of gas flow=100 slm (standard litres per minute, pressure=100 mbar (namely 10,000 Pa), temperature=1950° C., speed of gas flow=about 25 m/s.

Considering a cleaning process divided into three periods, as envisaged above, the gas flow is of greatest importance during the second period because the temperature is highest; during this second period, the parameter values indicated above, for example, could be used.

It is preferable for the gas flow during the second period to be much higher than the gas flow during the first period, preferably five to twenty times higher; in fact if there were a high gas flow during the period of increase of the temperature a lot of thermal energy would be wasted in heating the gas flow.

It is preferable for the gas flow during the third period to be substantially the same as or higher than the gas flow during the second period, preferably from one to three times higher; in fact a high gas flow during this period helps cool the chamber more quickly and therefore reduce the duration of the cleaning process without reducing its efficiency, the gas flow on the contrary maintaining its removal effect.

It is worth pointing out that, according to the present invention, it is also possible to envisage several different consecutive removal steps; these could have different durations, be conducted at different temperatures and use gas flows comprising different chemical species; these consecutive steps could be preceded by a single step involving an increase in the temperature and be followed by a single step involving a decrease in the temperature.

The cleaning process according to the present invention has a typical and advantageous application within an operating process of a CVD reactor for depositing semiconductor material on substrates, for example such as that partially shown in FIG. 2, equipped with a reaction chamber for depositions, for example such as that shown in FIG. 1.

The operating process according to the present invention envisages a growth process which comprises sequential and cyclical execution of:
a process for loading substrates inside the chamber;
a process for depositing semiconductor material on the substrates;
a process for unloading the substrates from the chamber;

after an unloading process, a process for cleaning the chamber according to the present invention is performed.

The frequency of the cleaning process depends on various factors including mainly the characteristics of the deposition process and the characteristics of the cleaning process.

FIG. 4 shows a time/temperature diagram relating to a part of the operating process according to the present invention performed in the reactor according to FIG. 2; FIG. 4 shows a time period LP corresponding to the unloading process, a time period RP1+DP+FP1 corresponding to the growth process, a time period UP corresponding to the unloading process, and a time period RP2+EP+FP2 corresponding to the cleaning process. More specifically, the time period corresponding to the growth process is divided into a time period RP1 for an increase in temperature, a time period DP for deposition, and a time period FP1 for a reduction in temperature, and the time period corresponding to the cleaning process is divided into a time period RP2 for an increase in temperature, a time period EP for removal, and a time period FP2 for a reduction in temperature.

The operating process according to the present invention may envisage advantageously a purging process performed after the loading process and before the deposition process; in the diagram according to FIG. 4, the purging process is not shown.

The purpose of the purging process is to remove from the reaction chamber gaseous substances which are undesirable or harmful for the growth process, in particular for the deposition process; a harmful substance is oxygen (a component of air) since it causes oxidation of the semiconductor material; an undesirable substance is nitrogen (a component of air) since it causes doping of the semiconductor material.

Harmful substances, typically the components of air, are able to penetrate into the reaction chamber typically during the substrate loading and unloading processes. This penetration may be avoided if the substrates yet to be treated are extracted from a “purging chamber” and if the substrates already treated are inserted into a “purging chamber”; typically the two purging chambers could coincide. The reactor partially shown in FIG. 2 does not envisage any “purging chamber” and therefore the purging process is necessary.

The most convenient way for removing the undesirable or harmful gases from the reaction chamber is to create a vacuum inside the reaction chamber. It is possible to proceed advantageously using the following steps:

a) fill the chamber with an inert gas, for example a “noble” gas, typically argon or helium, for example at 1 atm (namely about 100,000 Pa);

b) create inside the chamber a low-intensity vacuum, for example 10 Pa;

c) create inside the chamber a high-intensity vacuum, for example 0.0001 Pa.

Step b) may be performed, for example, by means of a normal vacuum pump.

Step c) may be performed, for example, by means of a turbo molecular pump.

Step a) is very short and may last, for example, about one minute.

Step b) is very short and may last, for example, about one minute.

Sep c) may last, for example, 10 or 15 minutes; obviously the time depends on the desired intensity of vacuum.

Typically, during step c), the temperature is increased by about 20° C. to about, for example, 1200° C. in order to favour desorption of the undesirable or harmful species.

Before deposition it is advisable to treat the surface of the substrates by means of etching of their surface. This treatment may be performed in an effective and efficient manner during the temperature increase period which precedes the deposition process, namely with reference to FIG. 4, the period RP1. For this purpose, it will be sufficient to introduce a flow of hydrogen at a speed, for example, of 20 m/s or 25 m/s. Advantageously the flow of hydrogen for pre-treatment of the substrates may start soon after the purging process; for example, it may start at about 1200° C. and end at about 1600° C.; typically, the hydrogen flow continues also during the deposition process, namely with reference to FIG. 4, during the period DP.

In the operating process according to the present invention, the chamber cleaning process may be performed, for example, after each unloading process. In this way, the material deposited on the walls of the chamber is removed soon after being deposited and therefore its damaging effects are minimized, in particular the risk associated with separation of particles from the walls is minimized.

The actual possibility of carrying out a cleaning process for each growth process is linked to the duration of the cleaning process according to the present invention, which is sufficiently short; in fact, if the cleaning process were much longer than the growth process, the CVD reactor would have a production output which is too low; the duration of the cleaning process is linked, in particular, to the temperature at which it is carried out.

The following example, which is purely indicative, helps one understand more clearly the above comment; if the speed of deposition of the silicon carbide at 1600° C. is 10 microns/hour and if the speed of removal of the silicon carbide at 2000° C. with a given hydrogen flow is 100 microns/hour, in order to remove the layer deposited in one hour, about six minutes will be sufficient; theoretically, there is a reduction in the production output of only 10%, which is very little when one takes into account the benefit associated with the reduced probability of defective substrates owing to falling particles.

The example given above may be considered in more detail with the aid of FIG. 4 which, as already mentioned, refers solely to an example of the operating process. The growth process envisages a time period RP1 for a temperature increase from about 20° C. to about 1600° C., a time period DP for deposition at 1600° C. and a time period FP1 for a temperature reduction from 1600° C. to about 20° C., and the cleaning process envisages a time period RP2 for a temperature increase from about 20° C. to about 2000° C., a time period EP for removal at about 2000° C. and a time period FP2 for a temperature reduction from about 2000° C. to about 20° C. In a reactor such as that partially shown in FIG. 2, the temperature may be increased and reduced at a speed, for example, of about 50° C./minute. In the example according to FIG. 4, the period RP1 lasts about 30 minutes, the period FP1 lasts about 60 minutes, the period RP2 lasts about 40 minutes, and the period FP2 lasts about 80 minutes; the period DP lasts about 60 minutes; the period EP lasts about 6 minutes; therefore the growth process lasts about 150 minutes and the cleaning process lasts about 126 minutes, namely slightly less than the growth process, with a reduction in the production output of about 45%. In the above calculation, however, the duration of the loading process, the unloading process and purging process has not been taken into consideration at all; if these time periods were to be taken into consideration, the cleaning process would last substantially less than the growth process and therefore the production output would be reduced only by 20%-30%.

As already mentioned, therefore, it is advantageous for the cleaning process to last a short time, less than the growth process, and preferably between ½ and ¼ of the growth process.

It is worth now making two comments with regard to the duration of some of the abovementioned periods. The duration of the periods LP and UP for loading and unloading the substrates depends greatly on the degree of automation of the CVD reactor. The removal of the material deposited on the walls does not occur solely during the period EP, but occurs when the temperature of the chamber is fairly high, for example higher than 1,500° C., if there is a gas flow; therefore, the removal starts during the period RP2 and ends during the period FP2 even though at the beginning and at the end it will be fairly slow, while during the period EP it will be at its greatest speed; on the basis of this observation it will be possible to choose correctly the duration of the various steps of the cleaning process.

In any case, if the production output of the CVD reactor is to be reduced by a very small amount, the operating process according to the present invention may envisage that the chamber cleaning process is performed after a predetermined number of unloading processes and therefore growth processes. This number may be chosen advantageously from the range of between two and ten.

The present invention, as regards both the cleaning process and the operating process, applies to CVD reactors for depositing semiconductor material on substrates.

The present invention is particularly advantageous in reactors where, during the deposition process, silicon carbide is deposited at a high temperature for the reasons already mentioned; for a good quality of the deposited material, deposition of the silicon carbide is performed at a temperature of between 1500° C. and 1700° C., preferably between 1550° C. and 1650° C., while for optimum removal, removal is performed at a temperature of between 1800° C. and 2400° C., preferably between 1900° C. and 2000° C.

The present invention is particularly useful in reactors where the walls of the reaction chamber are provided first of all with at least one surface layer of tantalum carbide or niobium carbide; as mentioned, the surface layer acts as protective layer for chambers made of graphite.

It should be noted that a surface layer of tantalum carbide or niobium carbide is particularly resistant and therefore results in the duration of the cleaning process being less critical; in fact, in the absence of a resistant surface layer, the duration of the cleaning process must be calculated with precision in order to avoid the removal not only of the material deposited on the walls but also of the material of the said walls.

In order to implement the cleaning process or the operating process according to the present invention, the CVD reactor must be equipped with suitable means. Often, in a CVD reactor, the mechanical parts, electrical parts and substances necessary for implementing a cleaning process according to the present invention, are already mostly present; moreover, a CVD reactor is generally equipped with a computerized electronic control system; therefore, in order to implement the present invention, it will often be substantially sufficient to modify the software program or the software programs controlling the reactor.

It is understood that the above description has been provided with reference to a CVD reactor with deposition of silicon carbide. However, it is applicable in all those cases of CVD reactors where the reaction chamber and/or reactor component is/are subject to the formation of unwanted incrustations or depositions, which must be removed in order to ensure correct operation of the reactor.

1. Process for cleaning the reaction chamber of a hot-wall CVD reactor, the walls of the chamber being lined with a protective layer of silicon carbide, tantalum carbide or niobium carbide, comprising the steps of:
heating the walls of the chamber to a temperature not lower than that for start of sublimation of the material to be removed; and
introducing a gas flow into the chamber.

2. Cleaning process according to claim 1, in which said material to be removed is silicon carbide.

3. Cleaning process according to claim 1, in which said gas comprises a noble gas, preferably argon or helium.

4. Process for cleaning a hot-wall CVD reactor, the walls of the reactor being lined with a protective layer of silicon carbide, tantalum carbide or niobium carbide, comprising the steps of:
heating the walls of the reactor, the heating temperature for the reactor walls being not lower than that for start of sublimation of the material to be removed; and
introducing a gas flow in contact with the walls of the reactor to be cleaned, said gas comprising at least one component which is reactive in relation to said material to be removed.

5. Cleaning process according to claim 1, in which said gas comprises hydrogen or hydrochloric acid or hydrobromic acid.

6. Cleaning process according to claim 1, in which said gas comprises hydrochloric acid and a noble gas.

7. Cleaning process according to claim 1, in which said gas comprises hydrochloric acid and hydrogen.

8. Cleaning process according to claim 1, in which the walls of the chamber are heated to a temperature higher than 1800° C., preferably between 1800° C. and 2400° C., more preferably between 1900° C. and 2000° C.

9. Cleaning process according to claim 1, comprising:
a first period where the temperature of the walls of the chamber is increased;
a second period where the temperature of the walls of the chamber is maintained;
a third period where the temperature of the walls of the chamber is reduced.

10. Cleaning process according to claim 9, in which the gas flow during the second period is greater than the gas flow during the first period, preferably five to twenty times greater.

11. Cleaning process according to claim 10, in which the gas flow during the third period is substantially the same as or greater than the gas flow during the second period, preferably one to three times greater.

12. Operating process of a hot-wall CVD reactor for depositing semiconductor material on substrates, the reactor being equipped with a reaction chamber for depositions, the walls of the chamber being lined with a protective layer of silicon carbide, tantalum carbide or niobium carbide, which envisages a growth process comprising the sequential and cyclical execution of:
a process for loading the substrates in the chamber;
a process for deposition of semiconductor material onto the substrates;
a process for unloading the substrates from the chamber;
characterized in that, after an unloading process, a process for cleaning the chamber according to one or more of claim 1 is performed.

13. Operating process according to claim 12, in which a purging process is performed after the loading process and before the deposition process.

14. Operating process according to claim 12, in which the chamber cleaning process is performed after each unloading process.

15. Operating process according to claim 12, in which the chamber cleaning process is performed after a predetermined number of unloading processes.

16. Operating process according to claim 15, in which said number ranges between two and ten.

17. Operating process according to claim 14, in which the cleaning process lasts less than the growth process.

18. Operating process according to claim 17, in which the cleaning process lasts between ½ and ¼ of the growth process.

19. Operating process according to one of claim 12, in which silicon carbide is deposited during the deposition process.

20. Operating process according to claim 19, in which the deposition of silicon carbide is performed at a temperature of between 1500° C. and 1700° C., preferably between 1550° C. and 1650° C.

21. Operating process according to one of claim 12, in which first of all the walls of the reactor are provided with at least one surface layer of tantalum carbide or niobium carbide.

22. CVD reactor for depositing semiconductor material on substrates, characterized in that it comprises means that implements an operating process according to one or more of claim 12.
